(19) United States
(12) Patent Application Publication
(10) Pub. No.: US 2008/0135892 A1
(43) Pub. Date: Jun. 12, 2008

(54) Carbon nanotube field effect transistor and method of making thereof

(76) Inventor: Paul Finnie, Ottawa (CA)

Correspondence Address: NATIONAL RESEARCH COUNCIL OF CANADA;1200 MONTREAL ROAD, BLDG M-58, ROOM EG12, OTTAWA, ONTARIO, K1A 0R6, omitted

(21) Appl. No.: 11/878,369

(22) Filed: Jul. 24, 2007

Related U.S. Application Data
(60) Provisional application No. 60/832,969, filed on Jul. 25, 2006.

(51) Int. Cl. H01L 29/78; H01L 21/336

(52) U.S. Cl. 257/288; 438/509; 977/938; 257/E29.255; 257/E21.409

(57) ABSTRACT

This invention relates to field effect transistors having carbon nanotube contacts and to a method of making these field effect transistors. The field effect transistors have better contacts as the source and drains as well as the bridge are made of carbon nanotubes. The fabrication of the proposed embodiment becomes possible by using a fabrication process which involves exposing the structure to two different temperatures.

This application claims the benefit of U.S. patent application 60/832,969 filed Jul. 25, 2006, which is herein incorporated by reference in its entirety.

This invention related to carbon nanotube field effect transistors and to a method of making said carbon nanotube field effect transistor, more specifically it is related to a two temperature method.

### BACKGROUND

Suspended single walled carbon nanotubes (SWNT) have great potential in a variety of different fields. These nanotubes have extraordinary optical properties, potential for photonic and optical applications, and are of special interest for field effect transistors. A simple method which can be used produce suspended SWNT is therefore of interest.

More specifically Carbon nanotubes can be used as field effect transistors if they are contacted by metallic leads at the source and drain and gated by an applied field. Presently contacts are made with metals such as gold, platinum or palladium. Gate fields are applied by metals or heavily doped silicon separated from the nanotube by air or oxide. The associated fabrication process involves many steps.

The existing fabrication is not only labour intensive, it is also not necessarily reliable. The performance of the transistor is determined by the contacts (i.e. the metal/nanotube junction), and the work function of the metal, as well as, the work function of the particular nanotube. Contacts are known to vary with nanotube diameter as well as choice of metal. Suspending the transconducting nanotube can therefore be difficult.

There is existent body of research on nanotube tube FETs beginning with S. Tans, R. M. Vershueren, C. Dekker, Nature 393 49 (1998). This is the first paper in which nanotube field effect transistors are presented, it discloses the original method of fabricating them—and their electrical characteristics.

Mats or forests of nanotubes have been grown by researchers, among the first successes was disclosed in Z. F. Ren, Z. P. Huang, J. W. Xu, J. H. Wang, P. Bush, M. P. Siegal, P. N. Provencio, Science 282 1105 (1998). Single walled nanotubes can be grown by Chemical Vapor Deposition (CVD) in many ways as demonstrated by different researchers, see for example J. Kong, H. T. Soh, A. M. Cassel, C. F. Quate, H. Dai, Nature 395 878 (1998).

Suspended nanotubes are of particular interest for optics. J. Lefebvre, Y. Homma, and P. Finnie, Phys. Rev. Lett. 90 217401 (2003). Demonstrate a method that can be used to fabricate suspended nanotube transistors or conventional non-suspended transistors. This paper only demonstrates that suspended nanotubes have superior optical properties, it does not address its application in transistors or their fabrication.

U.S. patent application 20060006377 (Golovchenko; Jene A.; et al.) describes a method of fabricating a suspended carbon nanotube field effect transistor. However the solution disclosed comprises a very involved fabrication method and does not disclose a carbon contacted device.

U.S. Pat. No. 6,677,624 Ihm; Ji Soon describes using single walled nanotubes as components of a transistor, substituting specific kinds of single walled nanotubes or bundles of these for what would conventionally be different semiconductor layers. However the method of fabrication is still quite involved and the resulting structure is different.

### SUMMARY OF THE INVENTION

An object of the present invention relates to a transistor structure with carbon nanotube contacts.

Another object of the invention is to propose a simple fabrication method for a transistor structure with carbon nanotube contacts.

These objects are met by providing an embodiment of a field effect transistor comprising: a conducting layer; an isolating layer covering said conducting layer; a carbon nanotube source covering a first end of said isolating layer; a carbon nanotube drain covering a second end of said isolating layer; the source and the drain being conducting carbon nanotubes; the source and the drain being separated by a channel; and a bridge, said bridge connecting the carbon nanotube source and the carbon nanotube drain; said bridge being a semiconducting carbon nanotube.

Or by providing an embodiment of a field effect transistor comprising: an isolating layer; where the isolating layer defines a trench in a middle region. On either side of the trench there is a source region and a drain region defined. a carbon nanotube gate electrode covers said trench; a carbon nanotube source covers said source region; a carbon nanotube drain covers said drain region; a carbon nanotube bridge connects the carbon nanotube source and the carbon nanotube source.

Or by providing an embodiment of a method which is a two temperature method for growing carbon nanotubes which comprises the following steps;

a) providing a substrate;

b) depositing a catalyst on the substrate using a deposition method to form an initial structure;

c) exposing the initial structure to a carbon containing gas for a given time;

d) heating the initial structure at a first temperature;

e) heating said resulting structure at a second temperature;

f) exposing said resulting structure to a carbon containing gas for a given time.

### BRIEF DESCRIPTION OF THE DRAWINGS

FIG. 1 illustrates an embodiment of a basic device.

FIG. 2 illustrates an embodiment of a carbon gated device.

FIG. 3 illustrates an embodiment of a nanotube device.

FIG. 4 illustrates a cross-sectional scanning electron micrograph for various growth temperatures.

FIG. 5 illustrates the abundance of radial breathing modes as a function of growth temperature.

FIG. 6 illustrates results obtained by two temperature suspension technique.

FIG. 7 illustrates thin carbon nanotubes supported by vertical aligned nanotube pillars.

### DETAILED DESCRIPTION OF THE INVENTION

Rather than use conventional metals as the contact to the nanotube, bundles, mats or forests of nanotubes are grown, which are metallic and as a result are macroscopic metal wires. Then single walled nanotubes bridging the metallic mats are grown. These CNT (carbon nanotube) mats can actually be used as leads or interconnects. They can also be used as gates.

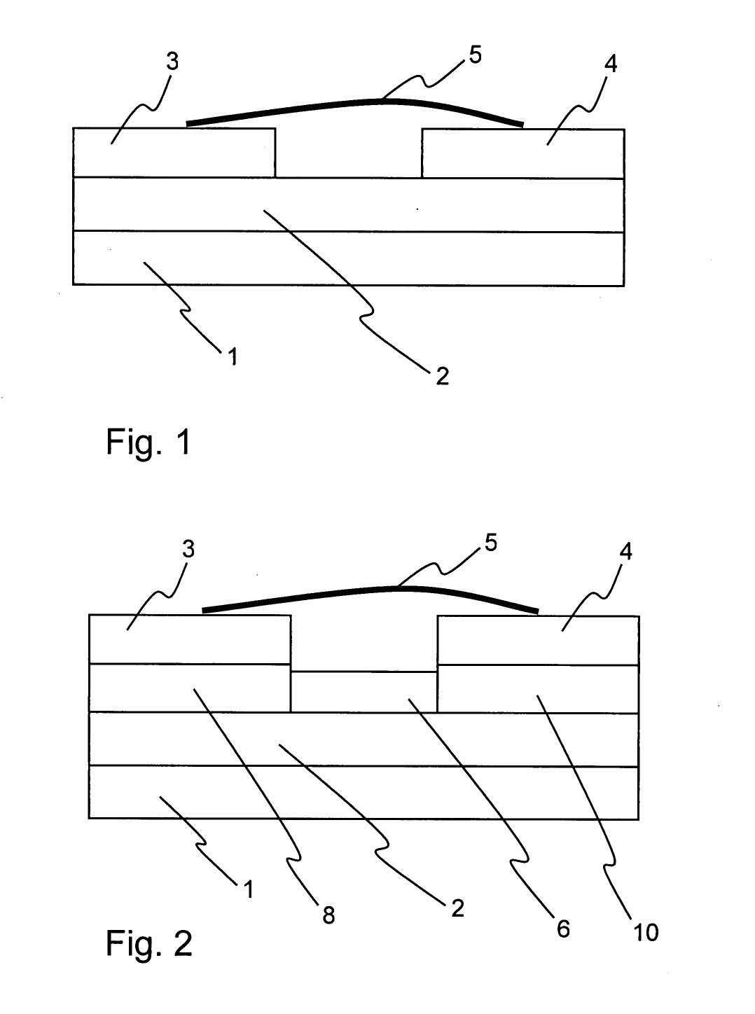

FIG. 1 illustrates an embodiment of the invention using contact carbon nanotubes. The carbon nanotube structure is composed of a conducting layer (1), the backgate. The backgate is made of a conducting material such as a silicon wafer. Deposited on the conducting layer (1) is an isolating layer (2), the isolating layer (2) is made of isolating material such as an oxide. On the first end of the isolating layer there is source (3) and on the other end of the isolating layer there is a drain (4). In an embodiment of the invention the source (3) and the drain (4) are conducting carbon nanotubes. These nanotubes can be bundles, mats or forests. In one embodiment of the invention the bundles, mats or forests of nanotubes are made of multiwalled carbon nanotubes, but they can also be single walled carbon nanotubes as long as there are a significant amount of them so that they conduct like metal.

The source (3) and drain (4) are connected by a carbon nanotube bridge. The bridge has to be semiconducting. In one embodiment of the invention the bridge is made of single walled carbon nanotube. However the bridge can be either single walled nanotube or multiwalled nanotube, so long as it is semiconducting. In one embodiment of this invention the connecting carbon nanotube is suspended, but it does not have to be, it can substantially cover the isolating layer between them so as to establish a contact.

FIG. 2 illustrates an embodiment of a carbon gated device where the front gate (6) is a forest, mat or bundle of nanotubes. The structure comprises of an isolating layer (2). A trench is etched in the isolating layer. The trench is covered by a carbon nanotube gate electrode (6). A source (3) covers one end of the unetched isolating layer (8) and a drain (4) covers the other end of the unetched isolating layer (10). The drain (4), and the source (3) are made of carbon nanotubes such as bundles, mats or forests. A bridge (5) connects both the drain and the source. In the embodiment illustrated in FIG. 2 it is suspended, but it does not need to be. The bridge has to be semiconducting. In one embodiment of the invention the bridge is made of single walled carbon nanotube. However the bridge can be either single walled nanotube or multiwalled nanotube, so long as it is semiconducting.

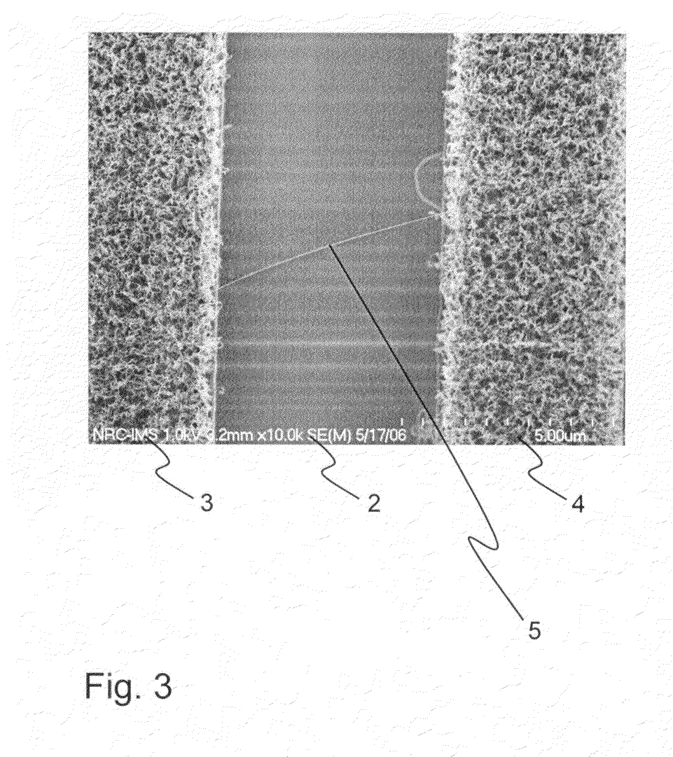

FIG. 3 illustrates an embodiment of an implemented device. The nanotube forest (3 and 4) can be seen on either side of the silicon dioxide (2). A suspended nanotube (5) can be seen bridging the source and the drain.

The nanotube which supplies the transistor is itself contacted by nanotubes. If it is backgated, a device can be fabricated in as little as one single lithography step. A front gated structure can also be fabricated easily, and optionally the front gate can be made of carbon nanotubes. Contacting a nanotube with other nanotubes provides a more reliable contact, because the nanotubes graphitic structure matches that of the contact.

Suspended single walled carbon nanotubes can be produced by suspending segments of single walled nanotubes over multiwalled carbon nanotubes. Nanotube diameter was found to be strongly related to the temperature at which nanotubes were grown. Samples grown at 600° C. were found to contain primarily multiwalled carbon nanotubes. In contrast samples grown at 850° C. had the greatest concentration of single walled carbon nanotubes. Samples grown at both temperatures (at about 600° C. followed by a temperature of about 850° C.) for yielded single walled carbon nanotubes suspended over multiwalled carbon nanotubes.

The characteristics of grown nanotubes depend strongly on the parameters of their growth process. For example altering the growth temperature changes the properties of the resulting nanotubes.

In an embodiment of the invention nanotubes are grown using a two temperature process. This method is used to grow the carbon nanotube mats, bundles and forest used in the carbon nanotube structure illustrated in FIGS. 1 to 3. A catalyst can be deposited on a substrate using various deposition methods. Such method comprise e-beam evaporation, sputtering, spin-coating, or imprinting. Different catalysts can be used such as cobalt and nickel, iron and aluminum.

In one embodiment of the invention a preheating step in air at 300 C is used. This step may not be necessary. It has been found to be useful, even if unnecessary, for iron on aluminum catalyst for example. The preheating temperature will therefore be dependent on the catalyst and the gases being used in the process.

The sample is then heated in a reducing atmosphere such as hydrogen/argon for several minutes. This step may not be necessary and will depend on the catalyst and choice of gases.

A carbon source is then supplied to grow the nanotube forest, mat or bundle. Sample can be grown for approximately 10 minutes at atmospheric pressure using carbon containing gases such as methane, ethylene, acetylene or ethanol vapor. The carbon containing gas may be purged out of the reactor. Again this step is optional.

The temperature is then increased to grow the bridging carbon nanotubes. This is done by again supplying a carbon containing gas such as methane, ethylene, acetylene, or ethanol vapor. The bridging nanotubes can be grown in several minutes. The growth speed may be slower or faster and is dependent on the exact growth conditions.

An embodiment of the invention consists of a method for making suspended single walled carbon nanotubes consisting in growing a sample with large catalyst areas at a first temperature for approximately 15 minutes. The first temperature ranging between 550° C. and 750° C., increasing the sample temperature to a second temperature. The second temperature ranging between 700° C. up to 950° C. Exposing the sample to a carbon containing gas. The carbon containing gas being selected from a group comprising methane, ethanol, ethylene, and acetylene gas.

### EXAMPLES

In one example of the method nanotubes were grown using thermal cold walled chemical vapor deposition (CVD)^{,1,2} using electron beam deposited metal film catalyst and ethanol vapor1^{,3} as the carbon source. Catalyst thin films were nominally 1 nm Fe on 1 nm Al evaporated on silicon substrates with 1 μm of silicon dioxide. Samples were then loaded into the growth chamber. After preheating in air at 300° C. samples were heated to their growth temperature in a 2% hydrogen, balance argon atmosphere. After holding the sample at a fixed temperature for 10 minutes, the hydrogen/argon gas flow was diverted through an ethanol bubbler before flowing into the reactor. Samples were exposed to a direct flow of ethanol vapor in the carrier gas for 20 minutes at atmospheric pressure. Following growth, the reactor was purged by bypassing the bubbler, and then the sample was cooled to room temperature.

A variety of samples were grown at various temperatures. The grown product was characterized by scanning electron microscopy (SEM), Raman spectroscopy, and photoluminescence (PL) imaging.^{,4,}

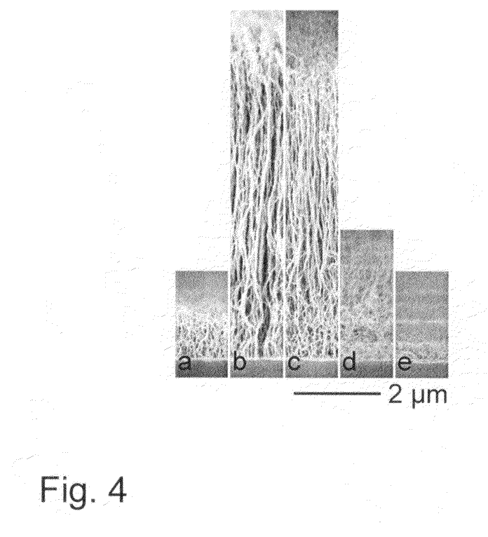

The growth temperature had a tremendous influence on the yield, the length of nanotubes, and the type of nanotube. It also greatly affected the collective arrangement of the nanotubes. This is best seen in cross-sectional SEM images on samples for which the catalyst film was patterned by shadow masking (FIG. 4). Looking at an inclined angle at the edge of the catalyst, one can readily see alignment in these nanotubes, and that temperature has a significant affect on alignment. The height of the vertically aligned nanotube forest is greatest with a growth temperature around 600° C. Outside of the temperature range shown in FIG. 4, the concentration of nanotubes was lower, and the nanotubes tended to lie on the surface, so cross sectional images are not shown.

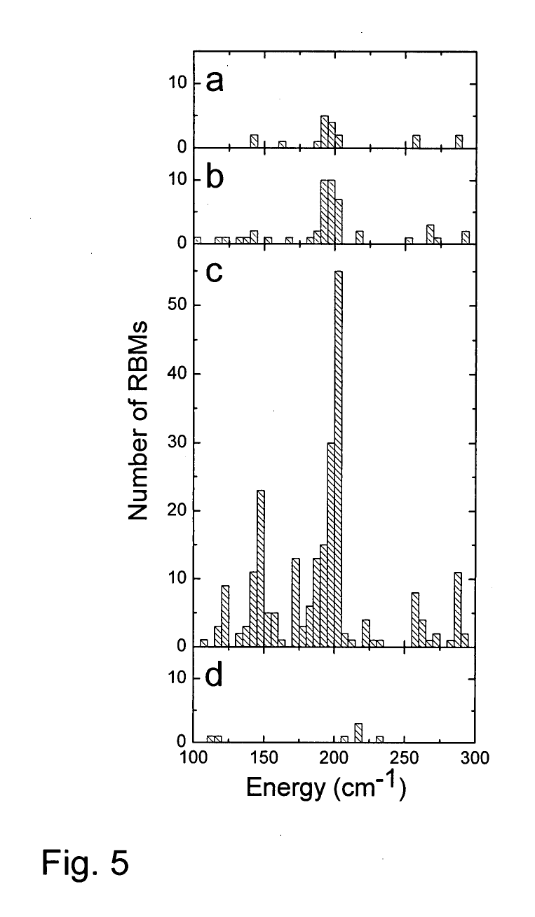

Raman spectra were taken for all samples using 633 nm excitation. Carbon nanotube related bands observed included the D, G. G′ and radial breathing mode (RBM). The concentration of RBMs is very sensitive to the growth temperature, as shown in 5. For each sample, one hundred widely spaced spots were examined by Raman spectroscopy using an approximately 1 μm diameter focal spot. Any sharp peak in the range 100 cm⁻¹ to 300 cm⁻¹ was counted as a single RBM. The number of RBMs seen is binned into 5 cm⁻¹ increment, with peaks seen throughout the 100 cm⁻¹ to 300 cm⁻¹ range. The number of RBMs/spot was 0.19, 0.48, 2.4, and 0.07 for 750° C., 800° C., 850° C. and 900° C., respectively. Out of one hundred points sampled, no radial breathing modes were found for temperatures above or below that shown in FIG. 5.

Combining growth regimes provided a simple technique to produce many laterally suspended SWNTs. An unpatterned sample was grown initially at 600° C. for approximately 15 seconds. This initial growth produced a layer of thick MWNTs, too short and sparse to become vertically aligned. The ethanol was purged out and the sample temperature increased to 850° C., after which ethanol was reintroduced for 20 minutes. The second growth segment caused thin nanotubes to grow over the layer of MWNTs.

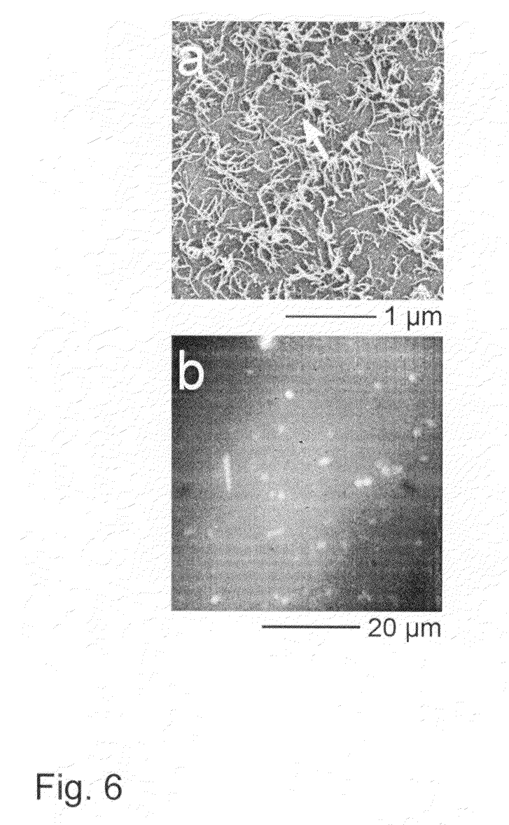

An SEM image of the results is shown in FIG. 6a. The thick, twisted MWNTs are readily seen. The thin, laterally suspended nanotubes are barely visible at this scale, so examples are highlighted with arrows. PL imaging was also used^{,4} to investigate these samples (FIG. 6b). PL imaging is very similar to conventional optical microscopy, except that in our case the illumination was with a ˜60 μm×˜40 μm elliptical spot generated by a defocused diode laser beam, and the detected radiation is the recombination of the illumination generated electron-hole pairs (excitons), which occur in the infrared for almost all semiconducting SWNTs. The detection was with a 2D InGaAs photodiode camera, sensitive to infrared radiation (˜1 μm to 1.6 μm), instead of the visible band used in conventional visible light microscopy. Luminescence is expected for semiconducting SWNTs, but not for bundles or MWNTs, so this is additional evidence that many of these thin, laterally suspended nanotubes are SWNTs.

A more organized, webbed network of large numbers of laterally suspended SWNTs was produced with a single photolithographic step. Rather than use a uniform catalyst film, the photoresist was spun onto the substrate, and exposed to a pattern of dots generated by a photomask. The exposed resist was developed, aluminum (1 nm) and iron (1 nm) deposited by e-beam evaporation, and the unexposed region lifted off. The result was various patterns of roughly circular catalyst dots of ˜2 μm diameter with typically ˜4 μm center-to-center spacing.

The CVD process was basically the same as above, but with a longer low temperature growth step to produce a dense forest. The sample was preheated in air, and then reduced in 2% hydrogen, balance argon at 600° C. for 10 minutes. Ethanol was then admitted for 20 minutes. This initial growth produced pillars of vertically aligned nanotubes. Ethanol was purged out of the reactor and the sample was heated to 850° C. After another 10 minute hold, ethanol was again introduced for another 20 minutes. This second growth resulted in the formation of SWNTs. Many of these SWNTs grew over the forest pillars and connected adjacent MWNT pillars.

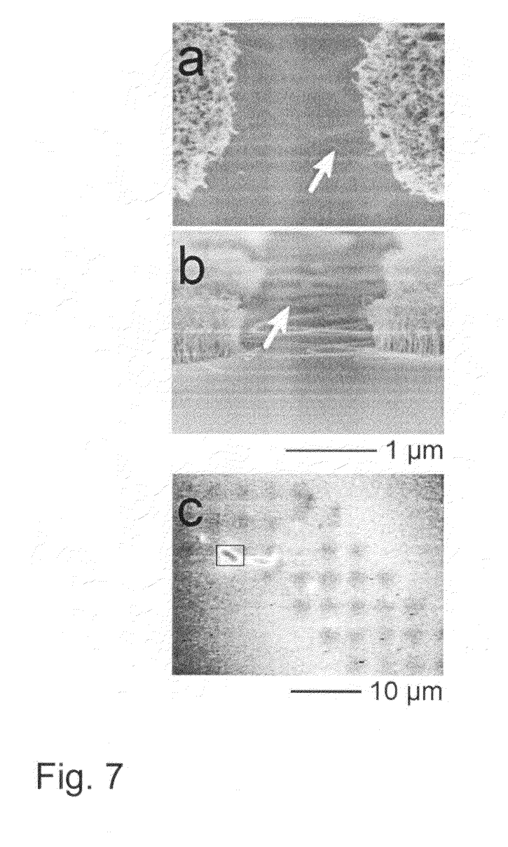

FIG. 7a shows a plan view image of a single SWNT, marked with an arrow, suspended between two MWNT pillars, left and right. There are also other suspended nanotubes visible in the picture, as well as some nanotubes which lie on the surface of the silicon dioxide. FIG. 7b shows the exact same pillar pair seen in a tilted angle view (85°). The vertical alignment and sharp edges of the MWNT “shrubs” are clear. Finally, FIG. 7c shows a PL image of the same area. Note that the magnification of the PL image is much lower than the SEM image. The box outlines the exact area imaged by SEM in FIG. 7a.

Other suspended nanotube segments visible in the SEM image are not noticeable in the PL image. There are several reasons for this, first the PL intensity is weaker when the excitation is not at a resonant wavelength, second nanotubes that are two large or two small to emit in our detection window ˜1.0 to 1.6 μm will be invisible, third PL is not expected from metallic SWNTs, bundles of SWNTs, or MWNTs. However, this is a straightforward method to generate large numbers of luminescent suspended SWNTs.

A simpler technique for producing large numbers of suspended SWNTs has been demonstrated. Using a two temperature CVD process, SWNTs can be suspended over top of pre-grown MWNTs. MWNTs either in the form of a thin layer grown on unpatterned substrates or vertically aligned pillars grown on patterned substrates can be used to laterally suspend SWNTs.

Other advantages that are inherent to the structure are obvious to one skilled in the art. The embodiments are described herein illustratively and are not meant to limit the scope of the invention as claimed. Variations of the foregoing embodiments will be evident to a person of ordinary skill and are intended by the inventor to be encompassed by the following claims.

### REFERENCES

Inclusion of a reference is neither an admission nor a suggestion that it is relevant to the patentability of anything herein.
1(̂) Chiashi, S.; Murakami, Y.; Miyauchi, Y.; Maruyama, S. Chem. Phys. Lett. 2004, 386(1-3) 89-94. Cold wall CVD generation of single-walled carbon nanotubes and in situ Raman scattering measurements of the growth stage
2 (̂) Finnie, P.; Li-Pook-Than, A.; Lefebvre, J.; Austing, D. G. Carbon 2006, XX, YY. Optimization of Methane Cold Wall Chemical Vapor Deposition for the Production of Single Walled Carbon Nanotubes and Devices
3 (̂) Maruyama, S.; Kojima, R.; Miyauchi, Y.; Chiashi, S.; Kohno, M. Chem. Phys. Lett. 2002, 360, 229. Low-temperature synthesis of high-purity single-walled carbon nanotubes from alcohol
4(̂) Tsyboulski, D. A.; Bachilo, S. M.; Weisman, R. B. Nano Lett. 2005, 5, 5, 975-979. Versatile Visualization of Individual Single-Walled Carbon Nanotubes with Near-infrared Fluorescence Microscopy

1. A field effect transistor comprising:
a conducting layer;
an isolating layer covering said conducting layer;
a carbon nanotube source covering a first end of said isolating layer;
a carbon nanotube drain covering a second end of said isolating layer;
the source and the drain being conducting carbon nanotubes;
the source and the drain being separated by a channel; and
a bridge, said bridge connecting the carbon nanotube source and the carbon nanotube drain;
said bridge being a semiconducting carbon nanotube.

2. The field effect transistor of claim 1 where the carbon nanotube source and the carbon nanotube drain are made of carbon nanotube bundles, or carbon nanotube mats, or carbon nanotube forests.

3. The field effect transistor of claim 1 or 2 where the bridge is a single walled carbon nanotube.

4. The field effect transistor of claim 1 or 3 where the bridge is suspended.

5. The field effect transistor of claim 1 or 2 where the source and the drain are made of multiwalled carbon nanotube.

6. A field effect transistor comprising:
an isolating layer;
said isolating layer defining a trench in a middle region defining a source region and a drain region on the isolating layer on either said of said trench;
a carbon nanotube gate electrode covering said trench;
a carbon nanotube source covering said source region;
a carbon nanotube drain covering said drain region;
a carbon nanotube bridge connecting said carbon nanotube source and said carbon nanotube source.

7. The field effect transistor of claim 6 where the carbon nanotube gate electrode, the carbon nanotube drain and the carbon nanotube source are made of carbon nanotube bundles, or carbon nanotube mats, or carbon nanotube forests.

8. The field effect transistor of claim 6 or 7 where the bridge is a single walled carbon nanotube.

9. The field effect transistor of claim 6 or 8 where the bridge is suspended.

10. The field effect transistor of claim 6 or 7 where the carbon nanotube gate electrode, the carbon nanotube drain and the carbon nanotube are multiwalled carbon nanotubes.

11. A two temperature method for growing carbon nanotubes comprising the steps of;
a) providing a substrate;
b) depositing a catalyst on the substrate using a deposition method to form an initial structure;
c) exposing the initial structure to a carbon containing gas for a given time;
d) heating the initial structure at a first temperature;
e) heating said resulting structure at a second temperature;
f) exposing said resulting structure to a carbon containing gas for a given time.

12. The method of claim 11 where the deposition method is e-beam evaporation or sputtering, or spin coating, or imprinting.

13. The method of claim 11 where the first temperature ranges from 550 to 750 degrees Celsius.

14. The method of claim 13 where the first temperature is 600 degrees Celsius.

15. The method of claim 11 or claim 13 where the second temperature ranges from 700 to 950 degrees Celsius.

16. The method of claim 13 or claim 15 where the second temperature is 850 degrees Celsius.

17. The method of claim 11 where the carbon containing gas is selected from one of methane, ethylene, acetylene, and ethanol vapor.

18. The method of claim 17 comprising the additional step of heating the structure in a reducing atmosphere such as hydrogen or argon after preheating the initial structure in air.

19. The method of claim 11 comprising the additional step of preheating the initial structure in air at approximately 300 degrees Celsius after step b.

20. The method of claim 11 comprising the additional step after step C of purging the carbon containing gas out.
